(19) United States
(12) Patent Application Publication
(10) Pub. No.: US 2004/0219443 A1
(43) Pub. Date: Nov. 4, 2004

(54) Method for wafer dicing

(76) Inventor: Kurt E. Spears, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 10/427,198

(22) Filed: May 1, 2003

(51) Int. Cl. G03F 7/36

(52) U.S. Cl. 430/30; 430/313

(57) ABSTRACT

A method comprises identifying good and bad die locations on a wafer, generating a custom dicing pattern according to the good and bad die locations, the custom dicing pattern comprising a plurality of multiple-die segments each having more than one die, and cutting the wafer according to the custom dicing pattern and producing a plurality of multiple-die segments.

### TECHNICAL FIELD OF THE INVENTION

The present invention relates generally to the field of integrated circuit device and, and more particularly to a method for wafer dicing.

### BACKGROUND OF THE INVENTION

One of the last steps in integrated circuit device fabrication is dicing or the process of cutting the semiconductor wafer into a plurality of individual die, each bearing an electronic circuitry. The die are typically arranged in a grid on the semiconductor wafer. Traditionally, the wafer is cut into uniform-sized die using a diamond saw or another suitable method. The die are then picked up and placed on circuit boards to be wire bonded or otherwise connected to the rest of the circuitry.

In some special applications, such as optical sensor module boards used in scanners, copiers, facsimile machines, digital senders, etc., a large number of die bearing light sensing circuitry has to be placed in precision alignment on the circuit board. The die are aligned end-to-end to achieve a dimension equivalent to the width of common paper or print media size, for example 8.5 inches. Precision alignment is typically achieved by using specialized and costly equipment. Any misalignment of the die will lead to pixel misalignment and other pixel errors. Therefore in a typical sensor module, where eight to sixteen die are used, multiple significant misalignment errors are possible.

### SUMMARY OF THE INVENTION

In accordance with an embodiment of the present invention, a method comprises identifying good and bad die locations on a wafer, generating a custom dicing pattern according to the good and bad die locations, the custom dicing pattern comprising a plurality of multiple-die segments each having more than one die, and cutting the wafer according to the custom dicing pattern and producing a plurality of multiple-die segments.

In accordance with another embodiment of the invention, an imaging device with an optical sensing module having a sensing circuit is manufactured by a method. The method comprises testing a plurality of die formed contiguously in a grid on a wafer and identifying good and bad die locations on the wafer, generating a custom dicing pattern according to the good and bad die locations, the custom dicing pattern comprising a plurality of multiple-die segments each having more than one die, and cutting the wafer according to the custom dicing pattern and producing a plurality of multiple-die segments.

In accordance with yet another embodiment of the present invention, a method comprises receiving a map of good die locations on a wafer, generating a custom dicing pattern according to the map of good die locations, the custom dicing pattern comprising a plurality of multiple-die segments each having M die, where M=O to N, and N is a positive integer. The method further comprises cutting the wafer according to the custom dicing pattern and producing the plurality of multiple-die segments.

### BRIEF DESCRIPTION OF THE DRAWINGS

For a more complete understanding of the present invention, the objects and advantages thereof, reference is now made to the following descriptions taken in connection with the accompanying drawings in which:

FIG. 1 is a top view of an exemplary semiconductor wafer showing proposed die cut lines according to an embodiment of the present invention;

FIG. 2 is a flow chart of a method of die cutting according to an embodiment of the present invention; and

FIG. 3 is a simplified top view of a circuit board according to an embodiment of the present invention.

### DETAILED DESCRIPTION OF THE DRAWINGS

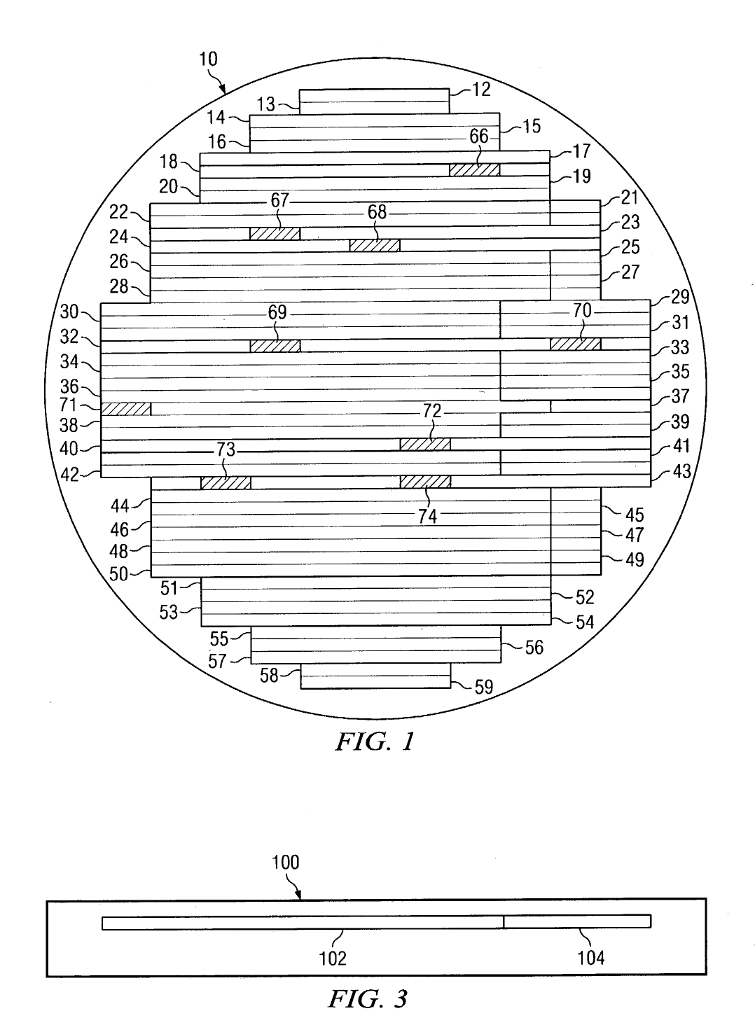

The preferred embodiment of the present invention and its advantages are best understood by referring to FIGS. 1 through 3 of the drawings, like numerals being used for like and corresponding parts of the various drawings.

FIG. 1 is a top view of a semiconductor wafer 10 showing proposed die cut lines and a mapping of die-segments to be cut therefrom according to an embodiment of the present invention. Wafer 10 has a mapping of a plurality of rows 12-59 of die that include die that have been determined to be “bad” or faulty 66-74. According to a particular application, a predetermined number of die is needed in precise linear alignment on the circuit board. For example, an optical sensor module for imaging applications requires eight or sixteen die placed in precise alignment in a straight row on, the circuit board. Therefore, for this particular application, it may be preferable to strive for eight-die groupings or segments. In other words, where possible, eight consecutive die in a row are not cut or separated from one another. The eight-die grouping may not be achievable where the grouping is interrupted by a “bad” die, or where the wafer width does not accommodate a row of eight consecutive die. Additionally, where a row does not have a number of die that is a multiple of eight, a die segment with seven or less die may remain after one or more eight-die segments are cut.

An example of how a wafer may be cut into multiple-die segments is shown in FIG. 1. A multiple-die segment is a series of consecutive die that are not cut or separated from one another. In this example, rows 12 and 13 each comprises a three-die segment, which is limited by the width of the wafer at that point. In rows 14-16, for example, the width of the wafer permits five-die segments. In rows 17, 19 and 20, the wafer width will only accommodate a seven-die segment. In row 18, because of the presence of a “bad” die 66, the longest continuous segment has only five die separated from a remaining “good” die by the “bad” die. In each row 21 and 22, an eight-die segment is possible with one remaining die. In row 23, a two-die segment is separated from a six-die segment by a “bad” die 67. Row 24 has two four-die segments separated by a “bad” die 68. Rows 25-28 can each accommodate an eight-die segment with one remaining die. Rows 29-31, occupying the widest portion of wafer 10, can each accommodate an eight-die segment with three remaining die. The three remaining die can be cut and separated individually or remain as a single segment depending on an algorithm that determines the die-segment pattern to be cut on wafer 10. It may be advantageous to have one or more one-die segments in order to assemble the necessary number of circuits on each circuit board. The next row, row 32, is interrupted by two non-consecutive “bad” die 69 and 70. As a result, row 32 can generate a three-die segment, a five-die segment, and a one-die segment, for example. The next four rows 33-36 in the example can each accommodate an eight-die segment with three remaining die. Row 37, because of a “bad” die 71 located at one end of the row, can accommodate an eight-die segment, but only a two-die segment at the other end. Rows 38 and 39 are identical and can each be cut into an eight-die segment and three one-die segments. It should be understood that rows 38 and 39 may each be cut into an eight-die segment and a three-die segment, or other combinations. An algorithm may be used to optimize the die cutting process on a wafer-by-wafer basis or on the basis of a batch of wafers. In row 40, because a “bad” die positioned in the middle of the row, two segments with six die and four die, respectively, can be cut. The next two rows, rows 41 and 42 can also be cut into an eight-die segment and three one-die segments. In row 43, the presence of two “bad” die causes the remaining “good” die to be divided into a one-die segment, a three-die segment, and a four-die segment. Rows 44-50 do not contain any “bad” die, and therefore can each be divided into one eight-die segment and one one-die segment. In rows 51-54, each respective row becomes a seven-die segment. In rows 55-57, each row is cut into a single five-die segment. The remaining two rows, rows 58 and 59 are cut into three-die segments.

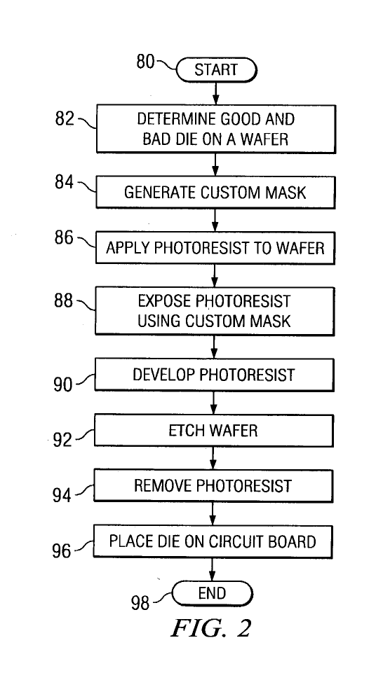

FIG. 2 is a flow chart of a simplified process 80 for die cutting according to an embodiment of the present invention. At the completion of semiconductor device fabrication, the wafer is tested to identify “good” and “bad” die, as shown in block 82. In this process, the circuit on each die is tested to ensure that it meets the desired electrical and design specifications. A probe tester or another special piece of equipment may be used to perform this test. Each “bad” die is noted by its position and may be marked. A map or some other “bad” die identification data associated with the particular wafer may be generated. Based on the position of the “good” and “bad” die, a custom mask delineating the lines to be followed for die cutting is generated, as shown in block 84. An algorithm to determine the etch lines takes into account of the “bad” die locations on the wafer, and the size of die segments desired on the circuit board. The algorithm may try to maximize the number of eight-die segments, for example, since that is the size of die segments used in the circuit boards. The algorithm also determines how to optimize the cutting of the rest of the die segments on a wafer-by-wafer basis, or on the basis of an entire batch of wafers.

For example, if the number and location of “bad” die are such that a large number of seven-die segments are generated, then an equally large number of one-die segments is also likely needed to complete the circuit boards that require eight-die segments. The algorithm may try to achieve this balance on a wafer-basis or on a batch-basis depending on the manufacturing needs. In general, the algorithm may attempt to produce an equal number of M-die segments and (N−M)-die segments, where N is the number of die in the desired segment (such as eight in the present example) and M is the number of die less than or equal to N, (M=0 to N) that results due to “bad” die. It may be seen that for any die defect pattern, many dicing patterns are possible. For example, if there are five seven-die segments, then the algorithm may attempt to produce five one-die segments (N=8, M=7 (N−M)=1); for five six-die segments, five two-die segments (N=8, M=6, (N−M)=2), etc.

Standard photolithography is performed to transfer the custom mask onto the wafer. For example, a light-sensitive photoresist is then applied to the surface of the wafer, as shown in block 86. To achieve an even thin layer and good coverage of the photoresist, the photoresist is typically spun onto the wafer. The wafer is then baked at a predetermined temperature to dry the photoresist. The custom mask is then aligned precisely over the wafer and the photoresist is then exposed to ultraviolet light, electron beam, or controlled laser for a predetermined amount of time, as shown in block 88. In block 90, the photoresist on the wafer is then developed by exposing it to or immersing it in a chemical solution and then dried. A post-bake step may be performed to harden the remaining photoresist. The photoresist now remains over areas of the wafer surface where etching is not desired. The wafer is then etched or micromachined into die and die-segments, as shown in block 92. An etch technique such as deep reactive ion etch may be used. The photoresist is then stripped, as shown in block 94, and the die-segments are separated and then individually placed on circuit boards, as shown in block 96. The process ends in block 98. Although deep reactive ion etch is described herein, other known die cutting methods such as using a diamond saw or other tools or methodologies may also be used. This process is applicable to wafers of various materials such as silicon, GaAs (gallium arsenide), sapphire-on-silicon, etc. with or without minor modifications. Furthermore, the chemical compounds and solutions used to develop the photoresist, to strip the photoresist, the bake temperatures, and details associated with other steps of the process are conventional or may be later developed.

For a circuit board that requires eight die in linear alignment, a number of different die and die-segment combinations can be used to complete the circuit board. For example, a three-die segment, a four-die segment, and a one-die segment may be used to assemble an eight-die sensing circuit. An eight-die configuration may also be composed of a two-die segment and two three-die segments. Other combinations are possible. All of these combinations that use multiple-die segments reduces the amount of precise alignment required to place these die on the circuit board. The results in savings in time and cost, as well as increased productivity and yield.

FIG. 3 is a top view of an exemplary circuit board 100 according to an embodiment of the present invention. Circuit board 100 is designed for a multiple-die optical sensor module and is shown having two multiple-die segments 102 and 104 in precise alignment. Each multiple-die segment may contain more than one circuit residing on more than one die. In our eight-die segment example, multiple-die segment 102 may include six die and multiple-die segment 104 may include two die. Therefore, instead of cutting and separating each die from the wafer, multiple-die segments are cut from the wafer so that the circuit boards may be assembled more easily without the repetitive and numerous precise alignment and placement of each die onto the board. In the example shown in FIG. 3, instead of having to align eight individual die, only one alignment step to align the two multiple-die segments is needed.

The wafer-dicing process of the present invention is applicable to other multiple-die segment configurations for other applications. For example, if a particular application requires that the die be positioned and aligned in a L configuration for scanning along two axes of an object, then the custom wafer dicing pattern can be modified to accommodate this new configuration with the goal of reducing the number of die alignments on the sensor module.

This new wafer-dicing process simplifies the manufacturing process and reduces the possibility of die alignment errors. Using this methodology, manufacturing costs are lowered because of lowered error rates and higher yields. Most importantly, the resultant multiple-die optical sensor modules have improved accuracy and are especially suitable to very fine resolution imaging applications.

What is claimed is:

1. A method, comprising:
identifying good and bad die locations on a wafer;
generating a custom dicing pattern according to the good and bad die locations, the custom dicing pattern comprising a plurality of multiple-die segments each having more than one die; and
cutting the wafer according to the custom dicing pattern and producing a plurality of multiple-die segments.

2. The method, as set forth in claim 1, wherein generating a custom dicing pattern comprises generating a map of good and bad die locations on the wafer.

3. The method, as set forth in claim 1, wherein generating a custom dicing pattern comprises generating a custom mask.

4. The method, as set forth in claim 1, wherein cutting the wafer comprises an etching process.

5. The method, as set forth in claim 4, wherein cutting the wafer comprises a deep reactive ion etching process.

6. The method, as set forth in claim 1, wherein cutting the wafer comprises:
applying a layer of photoresist onto the wafer;
aligning a custom mask over the wafer and exposing it to light;
developing the photoresist and exposing selected surface areas of the wafer;
etching the exposed surface areas of the wafer; and
removing the photoresist.

7. The method, as set forth in claim 1, wherein cutting the wafer further comprises producing at least one one-die segment.

8. The method, as set forth in claim 1, wherein generating the custom dicing pattern comprises maximizing the number of N-die segments, where N is the desirable number of consecutive die in a multiple-die segment.

9. The method, as set forth in claim 8, wherein generating the custom dicing pattern comprises generating an equal number of (N−M)-die segments and M-die segments, where M≦N.

10. The method, as set forth in claim 1, wherein generating the custom dicing pattern comprises generating a plurality of linear multiple-die segments.

11. An imaging device comprising an optical sensing module having a sensing circuit manufactured by a method, the method comprising:
testing a plurality of die formed contiguously in a grid on a wafer and identifying good and bad die locations on the wafer;
generating a custom dicing pattern according to the good and bad die locations, the custom dicing pattern comprising a plurality of multiple-die segments each having more than one die; and
cutting the wafer according to the custom dicing pattern and producing a plurality of multiple-die segments.

12. The imaging device, as set forth in claim 11, wherein generating a custom dicing pattern comprises generating a map of good and bad die locations on the wafer.

13. The imaging device, as set forth in claim 11, wherein generating a custom dicing pattern comprises generating a custom mask.

14. The imaging device, as set forth in claim 11, wherein cutting the wafer comprises an etching process.

15. The imaging device, as set forth in claim 14, wherein cutting the wafer comprises a deep reactive ion etching process.

16. The imaging device, as set forth in claim 11, wherein cutting the wafer comprises:
applying a layer of photoresist onto the wafer;
aligning a custom mask over the wafer and exposing it to light;
developing the photoresist and exposing selected surface areas of the wafer;
etching the exposed surface areas of the wafer; and
removing the photoresist.

17. The imaging device, as set forth in claim 11, wherein cutting the wafer further comprises producing at least one one-die segment.

18. The imaging device, as set forth in claim 11, wherein generating the custom dicing pattern comprises maximizing the number of N-die segments, where N is the desirable number of consecutive die in a multiple-die segment.

19. The imaging device, as set forth in claim 18, wherein generating the custom dicing pattern comprises generating an equal number of (N−M)-die segments and M-die segments, where M≦N.

20. The imaging device, as set forth in claim 11, wherein generating the custom dicing pattern comprises generating a plurality of linear multiple-die segments.

21. A method, comprising:
receiving a map of good die locations on a wafer;
generating a custom dicing pattern according to the map of good die locations, the custom dicing pattern comprising a plurality of multiple-die segments each having M die, where M=O to N, and N is a positive integer;
cutting the wafer according to the custom dicing pattern and producing the plurality of multiple-die segments.

22. The method, as set forth in claim 21, wherein generating a custom dicing pattern comprises generating a custom mask.

23. The method, as set forth in claim 21, wherein cutting the wafer comprises an etching process.

24. The method, as set forth in claim 23, wherein cutting the wafer comprises a deep reactive ion etching process.

25. The method, as set forth in claim 22, wherein cutting the wafer comprises:
applying a layer of photoresist onto the wafer;
aligning the custom mask over the wafer and exposing it to light;
developing the photoresist and exposing selected surface areas of the wafer;
etching the exposed surface areas of the wafer; and
removing the photoresist.

26. The method, as set forth in claim 21, wherein generating the custom dicing pattern comprises maximizing the number of N-die segments.

27. The method, as set forth in claim 26, wherein generating the custom dicing pattern comprises generating an equal number of (N−M)-die segments and M-die segments.

28. The method, as set forth in claim 21, wherein generating the custom dicing pattern comprises generating a plurality of linear multiple-die segments.
